(19) United States
(12) Patent Application Publication
(10) Pub. No.: US 2024/0026562 A1
(43) Pub. Date: Jan. 25, 2024

(54) INTERNALLY-HEATED HIGH-PRESSURE APPARATUS FOR SOLVOTHERMAL CRYSTAL GROWTH

(71) Applicant: SLT Technologies, Inc., Los Angeles, CA (US)

(72) Inventors: Mark P. D'EVELYN, Vancouver, WA (US); Paul M. VON DOLLEN, Brush Prairie, WA (US)

(21) Appl. No.: 18/355,676

(22) Filed: Jul. 20, 2023

Related U.S. Application Data
(60) Provisional application No. 63/424,802, filed on Nov. 11, 2022.
(60) Provisional application No. 63/390,803, filed on Jul. 20, 2022.

(51) Int. Cl. C30B 7/10; C30B 35/00

(52) U.S. Cl. CPC C30B 7/10; C30B 35/002

(57) ABSTRACT

Embodiments of the disclosure can include an apparatus for solvothermal crystal growth. The apparatus can include a cylindrical shaped enclosure, a cylindrical heater, a first end closure member, a load-bearing annular insulating member, and a first end plug. The cylindrical heater includes a first end, a second end and a cylindrical wall that extends between the first end and the second end, wherein an interior surface of the cylindrical wall defines a capsule region. The first end closure member is disposed proximate to the first end of the cylindrical heater, the first end closure member being configured to provide axial support for a capsule disposed within the capsule region. The load-bearing annular insulating member is disposed between an inner surface of the cylindrical shaped enclosure and an outer surface of the cylindrical wall of the cylindrical heater. The first end plug is disposed between the first end of the cylindrical heater and the first end closure. The load-bearing annular insulating member or the first end plug comprises a packed-bed ceramic composition, the packed-bed ceramic composition being characterized by a density that is between about 30% and about 98% of a theoretical density of a 100%-dense ceramic having the same composition.

### CROSS-REFERENCE TO RELATED APPLICATIONS

This application claims the benefit of U.S. provisional patent application Ser. No. 63/390,803, filed Jul. 20, 2022, and the benefit of U.S. provisional patent application Ser. No. 63/424,802, filed Nov. 11, 2022, which are both herein incorporated by reference.

### BACKGROUND

### Field

The present disclosure generally relates to processing of materials in supercritical fluids for growth of crystals useful for forming bulk substrates that can be used to form a variety of optoelectronic, integrated circuit, power device, laser, light emitting diode, photovoltaic, and other related devices.

### Description of Related Art

The present disclosure relates generally to techniques for processing materials in supercritical fluids, such as growth of single crystals. Examples of such crystals include metal nitrides, such as GaN, AlN, InN, InGaN, AlGaN, and AlInGaN. More specifically, embodiments of the disclosure include techniques for controlling parameters associated with material processing within a capsule or liner disposed within a high-pressure apparatus enclosure. Gallium nitride containing crystalline materials are useful as substrates for manufacture of optoelectronic and electronic devices, such as lasers, light emitting diodes, solar cells, photoelectrochemical water splitting and hydrogen generation devices, photodetectors, integrated circuits, and transistors, among other devices.

Supercritical fluids are used to process a wide variety of materials. A supercritical fluid is often defined as a substance beyond its critical point, i.e., critical temperature and critical pressure. A critical point represents the highest temperature and pressure at which the substance can exist as a vapor and liquid in equilibrium. In certain supercritical fluid applications, the materials being processed are placed inside a pressure vessel or other high-pressure apparatus. In some cases, it is desirable to first place the materials inside a container, liner, or capsule, which in turn is placed inside the high-pressure apparatus. In operation, the high-pressure apparatus provides structural support for the high pressures generated within the container or capsule holding the materials. The container, liner, or capsule provides a closed/sealed environment that is chemically inert and impermeable to solvents, solutes, and gases that may be involved in or generated by the process.

Supercritical fluids provide an especially ideal environment for growth of high-quality crystals, that is, a solvothermal process, in large volumes and low costs. In many cases, supercritical fluids possess the solvating capabilities of a liquid with the transport characteristics of a gas. Thus, on the one hand, supercritical fluids can dissolve significant quantities of a solute for recrystallization. On the other hand, the favorable transport characteristics include a high diffusion coefficient, so that solutes may be transported rapidly through the boundary layer between the bulk of the supercritical fluid and a growing crystal, and also a low viscosity, so that the boundary layer is very thin and small temperature gradients can cause facile self-convection and self-stirring of the reactor. This combination of characteristics enables, for example, the growth of hundreds or thousands of large a-quartz crystals in a single growth run in supercritical water. In some applications the fluid may remain subcritical, that is, the pressure or temperature may be less than the critical point. However, in all cases of interest here, the fluid is superheated, that is, the temperature is higher than the boiling point of the fluid at atmospheric pressure. The term “supercritical” will be used throughout to mean “superheated”, regardless of whether the pressure and temperature are greater than the critical point, which may not be known for a particular fluid composition with dissolved solutes.

Conventional pressure vessels for solvothermal crystal growth, or autoclaves, are externally heated. Consequently, to a first approximation, load-bearing elements of the pressure vessel experience essentially the same pressure and temperature as the crystal growth process. Commonly, the maximum pressure and temperature that can be achieved are limited by the creep characteristics of the material from which the pressure vessel body is fabricated, for example, a high-strength steel or a nickel-based superalloy. However, steel-based pressure vessels have insufficient properties for growth of materials such as the nitrides that require temperatures above 500 degrees Celsius, and nickel-based superalloys are very expensive and are difficult to scale to large dimensions.

Some of the limitations of externally-heated pressure vessels can be avoided by utilizing internal heating, so that load-bearing elements of the pressure vessel experience a similar pressure as the crystal growth process but are kept at much lower temperature, so that creep is less of an issue and, in many cases, high-strength steel alloys can be used as the load-bearing material. In some applications, an internal heater is separated from a high-strength enclosure by a load-bearing ceramic such as zirconia that acts as a thermal insulator, for example, as disclosed by D'Evelyn, et al. [U.S. Pat. No. 7,704,324] and by D'Evelyn [U.S. Pat. No. 8,097,081]. While this approach enables significantly-reduced costs compared to autoclaves fabricated from nickel-based superalloys, further cost reductions are desirable for large-scale manufacturing.

Therefore, what is needed is an improved internally-heated high-pressure apparatus that enables lower costs and greater scalability than superalloy-based autoclaves or internally-heated high-pressure apparatus that utilizes sintered zirconia as a load-bearing thermal insulator.

### SUMMARY

According to the present disclosure, apparatus related to processing of materials for growth of crystals is provided. More particularly, the present disclosure provides an improved internally-heated high-pressure apparatus for crystal growth of a material in a supercritical fluid, including crystal growth of a group III metal nitride crystal by an ammonobasic or ammonoacidic technique, but there can be others. In other embodiments, the present disclosure provides methods suitable for synthesis of crystalline nitride materials, but it would be recognized that other crystals and materials can also be processed. Such crystals and materials include, but are not limited to, GaN, AlN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

The present disclosure achieves these benefits and others in the context of known process technology. However, a further understanding of the nature and advantages of the present disclosure may be realized by reference to the latter portions of the specification and attached drawings.

Embodiments of the disclosure can include an apparatus for solvothermal crystal growth. The apparatus can include a cylindrical shaped enclosure, a cylindrical heater, a first end closure member, a load-bearing annular insulating member, and a first end plug. The cylindrical heater includes a first end, a second end and a cylindrical wall that extends between the first end and the second end, wherein an interior surface of the cylindrical wall defines a capsule region. The first end closure member is disposed proximate to the first end of the cylindrical heater, the first end closure member being configured to provide axial support for a capsule disposed within the capsule region. The load-bearing annular insulating member is disposed between an inner surface of the cylindrical shaped enclosure and an outer surface of the cylindrical wall of the cylindrical heater. The first end plug is disposed between the first end of the cylindrical heater and the first end closure. The load-bearing annular insulating member or the first end plug comprises a packed-bed ceramic composition, the packed-bed ceramic composition being characterized by a density that is between about 30% and about 98% of a theoretical density of a 100%-dense ceramic having the same composition. The cylindrical shaped enclosure can be configured to provide radial support for processing a material in a fluid at a pressure above about 5 megapascal (MPa) and less than about 500 MPa and temperatures above about 200 degrees Celsius and less than about 900 degrees Celsius. The packed-bed ceramic composition can have a thermal conductivity between about 0.1 and about 10 watts per meter-Kelvin.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIG. 1 is a schematic diagram showing an internally-heated high-pressure apparatus according to the prior art.

FIG. 2 is a schematic diagram showing an internally-heated high-pressure apparatus according to an embodiment of the present disclosure.

FIG. 3 is a schematic diagram showing an internally-heated high-pressure apparatus according to another embodiment of the present disclosure.

FIG. 4 is a schematic diagram showing a non-sintered annular insulator according to an embodiment of the present disclosure.

FIGS. 5A and 5B are schematic diagrams showing a method of making a non-sintered annular insulator according to an embodiment of the present disclosure.

FIGS. 6A and 6B are schematic diagrams showing packed-bed end-plugs according to two embodiments of the present disclosure.

FIG. 7A is a schematic diagram showing a packed-bed annular insulator according to an embodiment of the present disclosure.

FIG. 7B is a schematic diagram showing a method of making a packed-bed annular insulator according to an embodiment of the present disclosure

FIG. 8 is a schematic diagram showing is a simplified flow diagram of a method of processing a material within a supercritical fluid, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

According to the present disclosure, an apparatus for processing of materials for growth of crystals is provided herein. More particularly, the present disclosure provides an improved internally-heated high-pressure apparatus or vessel for crystal growth of a material in a supercritical fluid, including crystal growth of a group III metal nitride crystal by an ammonobasic or ammonoacidic technique, but there can be others. In other embodiments, the present disclosure provides methods suitable for synthesis of crystalline nitride materials, but it would be recognized that other crystals and materials can also be processed. Such crystals and materials include, but are not limited to, GaN, AN, InN, InGaN, AlGaN, and AlInGaN, and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

Approximating language, as used herein throughout the specification and claims, may be applied to modify any quantitative representation that could permissibly vary without resulting in a change in the basic function to which it may be related. Accordingly, a value modified by a term such as “about” may be not to be limited to the precise value specified. In at least one instance, the variance indicated by the term about may be determined with reference to the precision of the measuring instrumentation. Similarly, “free” may be combined with a term; and, may include an insubstantial number, or a trace amount, while still being considered free of the modified term unless explicitly stated otherwise.

The present disclosure focuses on improved internally-heated high-pressure apparatus for performing solvothermal crystal growth processes and processing materials in supercritical fluids. As noted above, solvothermal processes have a number of advantages for performing crystal growth in large volumes and are conventionally performed in externally-heated pressure vessels, which have limitations on maximum pressure and/or temperature, cost, and scalability. Internally-heated gas pressure vessels are well known in the art and are available in large volumes for maximum pressures in the range of approximately 50-200 megapascal (MPa). However, the use of a capsule for solvothermal crystal growth in such an apparatus may require independent control of both temperature and pressure, for example, as described by D'Evelyn, et al. [U.S. Pat. No. 7,704,324], whereas with conventional pressure vessels it suffices to control only the temperature.

Extremely high pressures for solvothermal processing can be accessed using an internally-heated pressure vessel where a solid, deformable, pressure transmission medium separates a cylindrical heater from a high strength enclosure, for example, as described by D'Evelyn, et al. [U.S. Pat. Nos. 6,398,867 and 7,101,433]. However, this approach may imply single-use heaters and cell parts, relatively high costs, and limited scalability.

A load-bearing, thermally-insulating, hard, sintered ceramic such as zirconia between a cylindrical heater and a high-strength enclosure can be used to perform a solvothermal process at pressures in the range of approximately 25-2000 MPa and process temperatures in the range of 400-1200 degrees Celsius, for example, as described by D'Evelyn, et al. [U.S. Pat. No. 7,704,324] and by D'Evelyn [U.S. Pat. No. 8,097,081]. However, sintering requirements utilized in these conventional vessel designs tend to limit the maximum value of a minimum dimension of ceramic parts, particularly a high-thermal-expansion composition such as zirconia, which can lead to a requirement for a large number of parts for a large-volume apparatus. In addition, precision grinding of large ceramic parts can be undesirably costly.

It is an object of the present disclosure to provide an internally-heated high-pressure apparatus capable of performing solvothermal crystal growth at process pressures in the range of approximately 25-500 MPa, or 30-300 MPa, and process temperatures in the range of 200-900 degrees Celsius with improved scalability and reduced cost compared to previous designs.

As a point of reference, zirconia is a ceramic that combines low thermal conductivity, high flexural and compressive strength, high fracture toughness, and commercial maturity, for load-bearing high temperature applications such as those considered herein. Zirconia ceramics are typically manufactured by forming zirconia powder, often blended with hafnia and stabilized with one or more of magnesia, calcia, ceria, or yttria, into a green body, cold iso-statically pressing at pressures in the range of 80-500 MPa, dewaxing, and sintering at temperatures in the range of 1350-1800 degrees Celsius.

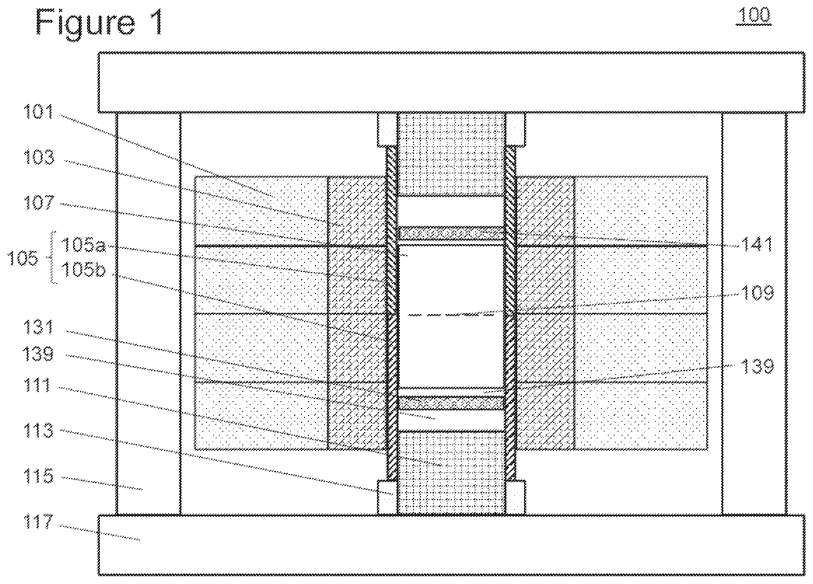

FIG. 1 is a simplified diagram of an internally-heated high-pressure apparatus according to a prior-art embodiment for processing material in a supercritical fluid using zirconia or other sintered materials as a load-bearing thermal insulator. Referring to FIG. 1, the apparatus 100 may include a stack of one or more ring assemblies to provide radial confinement, comprising a high strength enclosure ring 101 and at least one ceramic ring 103. Ceramic ring 103 may consist essentially of a sintered ceramic composition, such as zirconia or another low-thermal-conductivity material. The stack may include greater than 2, greater than 5, greater than 10, greater than 20, greater than 30, greater than 50, or greater than 100 ring assemblies. The stack surrounds a cylindrical heater or heating member 105 and capsule 107 and may be supported mechanically by at least one support plate (not shown). In other words, the heating member or heater, which includes a heater wall, may be positioned between the capsule and one or more radial restraint structures comprise a high strength enclosure ring and a thermally-insulating, load-bearing structure, for example, a ceramic ring. The stack may provide radial confinement for pressure generated within capsule 107 and transmitted outward through cylindrical heater 105. Cylindrical heater 105 may include an upper heater 105a and a lower heater 105b. Each of upper heater 105a and lower heater 105b may include one, two, or more independently-controllable hot zones that include heating elements that are disposed within the wall of the cylindrical heater 105. Upper heater 105a and lower heater 105a may be physically joined into a unitary component but are typically independently controllable. The interior of cylindrical heater 105 may define a processing chamber, into which capsule 107 may be placed. In the case that the ring assemblies in the die stack are comprised of high strength enclosure ring 101 and ceramic ring 103, there may be an interference fit between the two members in each ring assembly. Means for external cooling of the one or more ring assemblies or radial restraints may be provided. In certain embodiments, capsule 107 includes an inner capsule member and an outer capsule member (not shown).

Axial confinement of pressure generated within capsule 107 may be provided by end plugs 111, crown members 117, and tie rods or tie rod fasteners 115. End plugs 111 may include or consist of a sintered ceramic such as zirconium oxide or zirconia. End plugs 111 may be surrounded by end plug jackets 113. End plug jackets may provide mechanical support and/or radial confinement for end plugs 111. End plug jackets 113 may also provide mechanical support and/or axial confinement for cylindrical heater 105. End plug jackets 113 may include or consist essentially of steel, stainless steel, an iron-based alloy, a nickel-based alloy, or the like. In certain embodiments, tie rod fasteners 115 are arranged in a configuration that provides axial loading of two or more ring assemblies.

High strength enclosure rings 101, crown members 117, and tie rod fasteners 115 may include or consist of a material selected from a group consisting of steel, low-carbon steel, SA723 steel, SA266 carbon steel, 4340 steel, A-286 steel, iron based superalloy, 304 stainless steel, 310 stainless steel, 316 stainless steel, 340 stainless steel, 410 stainless steel, 17-4 precipitation hardened stainless steel, zirconium and its alloys, titanium and its alloys, and other materials commonly known as Monel, Inconel, Hastelloy, Udimet 500, Stellite, Rene 41, and Rene 88. One or more of these components may undergo a heat treatment operation.

Apparatus 100 may include a pressure transmission medium 139 proximate to the axial ends of capsule 107 and to end plugs 111 according to a specific embodiment. Pressure transmission medium 139 may include multiple components, for example, one or more disks. The pressure transmission medium may comprise sodium chloride, other salts, or phyllosilicate minerals such as aluminum silicate hydroxide or pyrophyllite, or other materials, according to a specific embodiment. In certain embodiments, pressure transmission medium 139 may comprise one or more of metal halides, such as NaCl, NaBr, AgCl, AgBr, CaF₂, or SrF₂, graphite, hexagonal boron nitride, talc, soapstone, gypsum, limestone, alabaster, molybdenum disulfide, calcium carbonate, magnesium oxide, zirconium oxide, merylinite clay, bentonite clays, or sodium silicate.

A baffle 109 may be positioned within capsule 307, dividing the internal volume of capsule 107 into an upper chamber and a lower chamber. Baffle 109 may include one or more disks, conical portions, spheroidal portions, or the like, with one or more perforations and annular gaps with respect to the inner diameter of capsule 107 to allow for restricted fluid motion through the baffle. Baffle 109 may be formed from a metal or metal containing material.

Internally-heated high-pressure apparatus 100 may further comprise a bottom end heater 131 and/or a top end heater 141 that are thermally coupled to the bottom portion and the top portion of capsule 107, respectively.

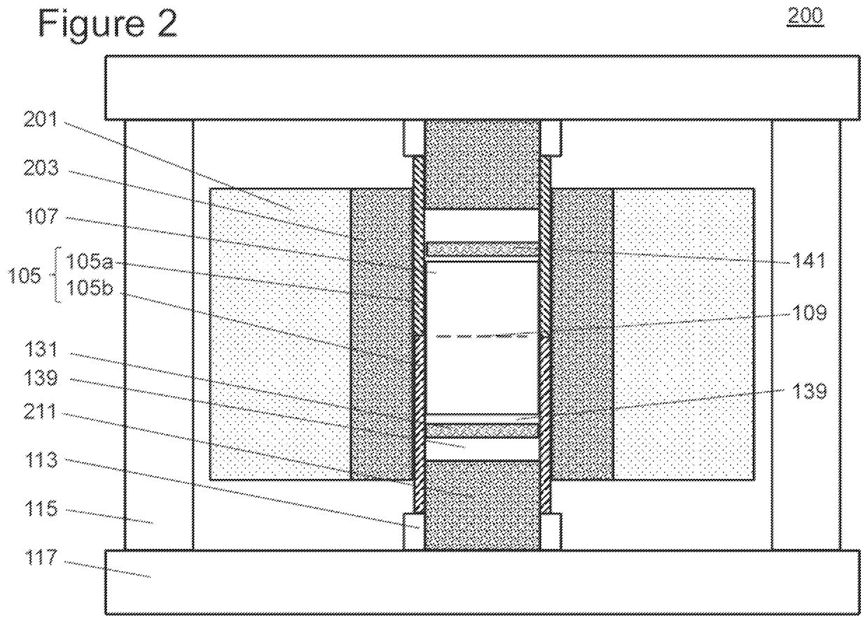

FIG. 2 is a simplified diagram of an improved internally-heated high-pressure apparatus 200 according to an embodiment of the present disclosure using one or more packed-bed members as a load-bearing thermal insulator. As shown, the present invention provides an apparatus for high pressure crystal or material processing, e.g., GaN, AlN, InN, InGaN, AlGaN, and AlInGaN. Other processing methods include hydrothermal crystal growth of oxides and other crystalline materials, hydrothermal or ammonothermal syntheses, and hydrothermal decomposition, and others. Of course, there can be other variations, modifications, and alternatives.

Many of the components of the inventive apparatus shown in FIG. 2 are similar or identical to the corresponding components in the prior art apparatus of FIG. 1. However, in some embodiments, the ceramic rings 103 used in the internally-heated high-pressure apparatus 100 are replaced by packed-bed annular insulator 203 utilized in the improved internally-heated high-pressure apparatus 200. In certain embodiments end plugs 111, fabricated from a sintered ceramic, are replaced by packed-bed end plugs 211, fabricated from one or more of the compositions described in detail below. In preferred embodiments, rather than radial support for capsule 307 being provided by a stack of high strength enclosure rings 101, radial support for capsule 307 is instead provided by cylindrical enclosure 201, also referred to herein as a high-strength enclosure, which may be a monolithic part such as a cylinder.

Referring again to FIG. 2, a high-pressure apparatus and related methods for processing supercritical fluids are disclosed. In certain embodiments, the packed-bed members are employed as components of an internally-heated high-pressure apparatus. The apparatus provides adequate containment in all directions which, for a typical cylindrical vessel, can be classified as radial and axial. Furthermore, depending on the specifics of the design parameters, the apparatus is capable of operating at temperatures between 200 degrees Celsius and 900 degrees Celsius, pressures between about 5 MPa and about 500 MPa, and for whatever length of time is necessary to grow satisfactory bulk crystals, for example, between about 1 hour and about 200 days.

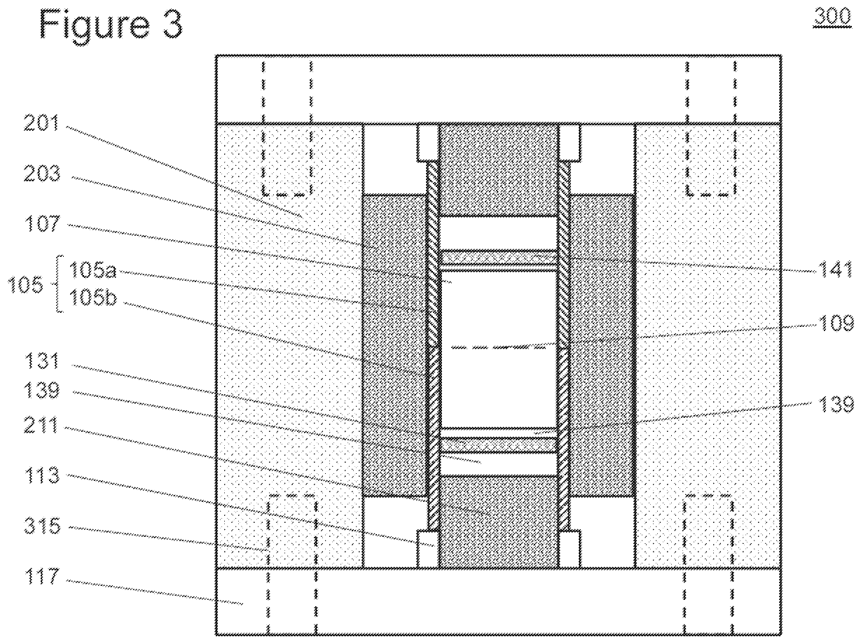

Another embodiment of the invention according to the present disclosure is shown in FIG. 3. With cylindrical enclosure 201 now being a monolithic part, axial support via crown members 117 may be provided by attaching crown members 117 to the cylindrical enclosure 201 by means of fasteners 315 rather than via tie rod fasteners 115. Fasteners 315 may include or consist of bolts, threaded rod, screws, interlocking features, or the like.

Cylindrical enclosure 201 and fasteners 315 may include or consist of a material selected from a group consisting of steel, low-carbon steel, SA723 steel, SA266 carbon steel, 4340 steel, A-286 steel, iron based superalloy, 304 stainless steel, 310 stainless steel, 316 stainless steel, 340 stainless steel, 410 stainless steel, 17-4 precipitation hardened stainless steel, zirconium and its alloys, titanium and its alloys, and other materials commonly known as Monel, Inconel, Hastelloy, Udimet 500, Stellite, Rene 41, and Rene 88. One or more of these components may undergo a heat treatment operation.

In an alternative embodiment, crown members 117 are held in place and supported axially by means of a yoke rather than by fasteners.

In certain embodiments, one or more packed-bed members includes a non-sintered ceramic composition. In general, non-sintered ceramic compositions, or green bodies, have relatively poor mechanical properties, except in compression. For example, the tensile or flexural fracture strength of the non-sintered ceramic compositions may be less than 100 MPa, less than 50 MPa, less than 20 MPa, or less than 10 MPa. In addition, non-sintered ceramic compositions are generally avoided in load-bearing applications due to the effects of surface abrasion associated with loading and unloading of internal components and cyclic loading and unloading, which may cause fretting wear of a non-sintered ceramic composition and generation of free powder. Moreover, if the free powder is allowed to separate from the green body, continued wear may cause rapid deterioration of the green body.

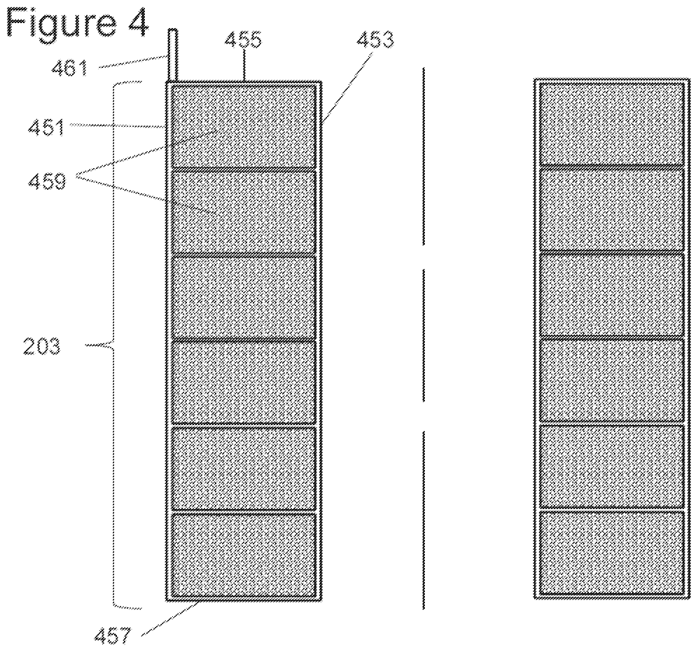

The stability of non-sintered ceramic compositions as load-bearing thermal insulators in the high-pressure apparatus applications disclosed here may be improved by placing them inside an enclosure or can-shaped structure. In certain embodiments, as shown schematically in FIG. 4, packed-bed annular insulator 203 may include one or more non-sintered annular components 459 in an enclosure consisting of outer annular enclosure 451, inner annular enclosure 453, upper annular enclosure 455, and lower annular enclosure 457. Each of outer annular enclosure 451, inner annular enclosure 453, upper annular enclosure 455, and lower annular enclosure 457 may include or consist of steel, stainless steel, carbon steel, nickel, nickel-based alloy, Inconel® nickel-chromium and iron alloy, Hastelloy® nickel-molybdenum-chromium ahoy, René 41® nickel-based alloy, Waspalloy® nickel-based alloy, Mar-M 247® polycrystalline cast nickel-based alloy, Monel® nickel-copper alloy, Stellite® cobalt-chromium alloy, copper, copper-based alloy, zirconium, niobium, molybdenum, tantalum, tungsten, rhenium, platinum, platinum-based alloy, palladium, iridium, ruthenium, rhodium. osmium, titanium, vanadium, chromium, iron, iron-based alloy, gold, silver, or aluminum, combinations thereof, and the like. In a specific embodiment, each of outer annular enclosure 451, inner annular enclosure 453, upper annular enclosure 455, and lower annular enclosure 457 are fabricated from stainless steel 304, stainless steel 316, or a similar composition. Outer annular enclosure 451 and inner annular enclosure 453 may have a cylindrical shape, with a height between about 150 millimeters and about 50 meters, or between about 1 meter and about 25 meters. The outer annular enclosure 451 can have an outer diameter between about 25 millimeters and about 5 meters, or between about 100 millimeters and about 3 meters, a wall thickness between about 0.1 millimeter and about 50 millimeters or between about 1 millimeter and about 10 millimeters and may be formed by rolling and welding, machining, casting, or the like. The inner annular enclosure can have an inner diameter that is between about 5 millimeters and about 1 meter less than the outer diameter of the outer annular enclosure 451, and have a wall thickness between about 0.1 millimeter and about 50 millimeters or between about 1 millimeter and about 10 millimeters and may be formed by rolling and welding, machining, casting, or the like. Upper annular enclosure 455 and lower annular enclosure 457 play the additional role of providing axial mechanical support for non-sintered components 459, which may otherwise be placed in axial tension by an internal compressive load. Upper annular enclosure 455 and lower annular enclosure 457 may have a thickness between about 0.5 millimeter and about 50 millimeters, or between about 1 millimeter about 25 millimeters and may be formed by machining, water-jet cutting, electric-discharge machining, or the like, from plate, sheet, or foil stock. Outer annular enclosure 451, inner annular enclosure 453, upper annular enclosure 455, and lower annular enclosure 457 may be joined to one another by one or more of welding, brazing, or fastening.

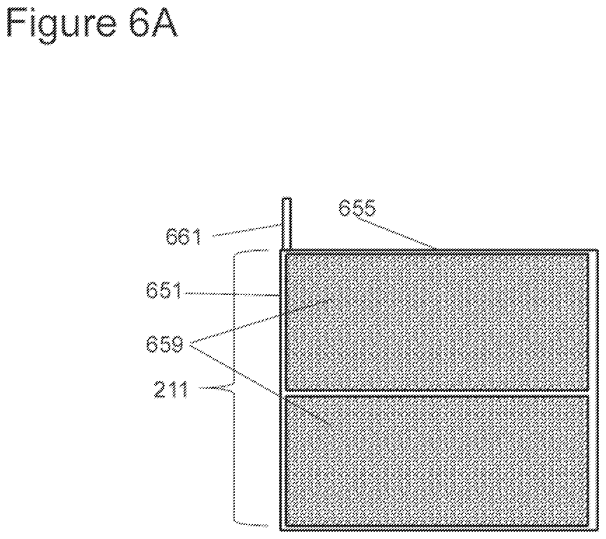

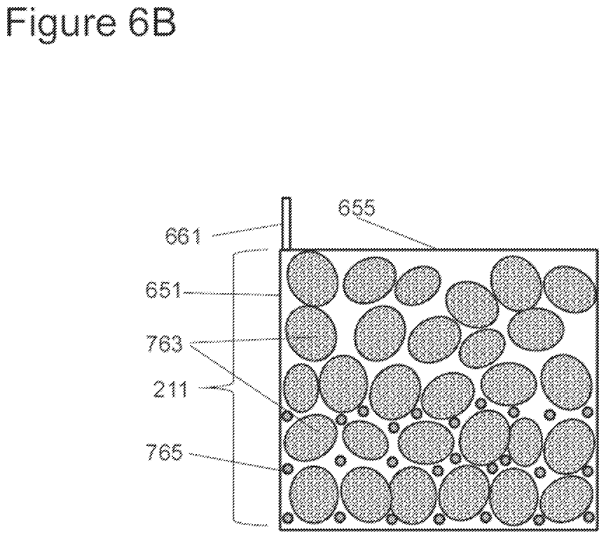

Referring again to FIG. 2, packed-bed end plugs 211 may be fabricated in a similar way as packed-bed annular insulator 203. For example, as shown schematically in FIG. 6A, packed-bed end plugs 211 may be fabricated by placing one or more non-sintered cylindrical components 659 in an enclosure consisting of cylindrical enclosure 651 and end disk enclosures 655, which may be joined to one another by one or more of welding, brazing, or fastening. In some embodiments, the cylindrical enclosure 651 may be formed from a similar material as that used to form one or more of the outer annular enclosure 451, inner annular enclosure 453, upper annular enclosure 455, or lower annular enclosure 457, and have a thickness between about 0.5 millimeter and about 50 millimeters, or between about 1 millimeter about 25 millimeters.

Non-sintered annular components 459 and non-sintered cylindrical components 659 may include or consist of a green body formed from or more powder compositions. The powders may include or consist of one or more of zirconia, magnesia-partially-stabilized zirconia, yttria-stabilized zirconia, hafnia, magnesia, yttria, calcia, ceria, silica, alumina, Gd₂Zr₂O₇, (Zr,Hf)₃Y₄O₁₂, tungsten niobate, a rare earth phosphate, a rare earth molybdate, or a mineral formed from one or more of these compositions. The powders may also include a composition that may inhibit sintering. In certain embodiments, the sintering inhibitor includes one or more of graphite, boron nitride, molybdenum disulfide, and tungsten disulfide. In certain embodiments the sintering inhibitor includes or consists of a powder. In certain embodiments the sintering inhibitor includes or consists of a coating. The powders may be prepared by methods that are well known in the art, such as at least one of ball milling, attrition milling, calcination, spray pyrolysis, hydrothermal preparation, spray forming, reactive plasma preparation, and sol-gel formation. The particle size of the powders may be between about 100 nanometers and about 150 micrometers, or between about 2 micrometers and about 100 micrometers, or between about 3 micrometers and about 50 micrometers. The powders may be mixed. The mixing may be performed by an operation such as ball milling or attrition milling. High-purity zirconia or alumina balls or rods may be provided as the milling media. In some embodiments, mixing is performed in a liquid carrier such as water, methanol, ethanol, isopropanol, acetone, hexane, or the like. A polymer, such as polyvinyl alcohol (PVA) or polyvinyl butyral (PVB) may be provided as an additional mixing promoter. The liquid carrier may be removed by drying the slurry after mixing.

In some embodiments, mixed ceramic powder is formed directly by formation from liquid or gas precursors. In the case of zirconia-containing powder compositions, it may be preferable to form partially-stabilized zirconia powder particles containing approximately 8 mole percent magnesia or calcia, or tetragonal-stabilized zirconia powder particles containing approximately 2 to 8 mole percent yttria, rather than mixing the pure components, so as to ensure the desired low-thermal-conductivity phases in the powder. In certain embodiments, precursors are formed by preparing a nitrate or chloride solution comprising the desired cations in the appropriate relative concentrations, forming precipitates by mixing with a solution such as ammonium oxalate or ammonium hydroxide, collecting the powder by sedimentation or filtration, drying, and heating to a thermal decomposition temperature between about 600 degrees Celsius and about 1000 degrees Celsius. The dried ceramic powder may be ground and sieved, and may be calcined, for example, in air. Disaggregation of the powder particles may be achieved by jet milling.

The ceramic powders may be formed into a shaped green body by at least one of uniaxial pressing in a die, isostatic pressing, drying in a mold, and slip casting. In certain embodiments, an annular green body is formed by wet-bag isostatic pressing around a cylindrical mandrel and formed into a precision part by green machining. In certain embodiments, an annular green body is formed by uniaxial pressing between annular anvils around a cylindrical mandrel. In certain embodiments, particularly for larger components, a radial segment of an annular green body is formed by uniaxial pressing in a punch-die set having a cross section corresponding to a radial segment of an annulus. In certain embodiments, the radial segment may consist of one-half, one-third, one-quarter, one-sixth, one-eighth, one-twelfth, one-sixteenth, one twenty-fourth, or one thirty-second of an annulus. In certain embodiments, the height, or thickness of the annular green body or radial segment thereof may be between about 10 millimeters and about 5 meters, between about 20 millimeters and about 2 meters, or between about 50 millimeters and about 1 meter. The green bodies may be formed by uniaxially pressing, or cold isostatically pressing, at a pressure between about 10 MPa and about 1000 MPa, between about 100 MPa and about 750 MPa, or between about 200 MPa and about 500 MPa. In general, a more uniform density can be achieved by isostatic pressing, compared to uniaxial pressing, particularly for parts greater than about 25-100 millimeters in height, but green machining is more likely to be needed to achieve precise dimensions. In certain embodiments, the green body is formed by hot isostatic pressing, at a pressure between about 50 MPa and about 200 MPa and a temperature between about 200 degrees Celsius and about 1200 degrees Celsius, followed by green machining. In preferred embodiments, the green body is formed at a compaction pressure that is greater, by at least 20%, at least 50%, or at least 100% than the intended pressure for the solvothermal crystal growth process.

Referring again to FIG. 4, after baking, de-waxing, and optional green machining, non-sintered annular components 459 may be placed into an enclosure defined by outer annular enclosure 451, inner annular enclosure 453, upper annular enclosure 455, and lower annular enclosure 457 and the latter closed and sealed, for example by welding. In certain embodiments, residual air is removed from the interior of packed-bed annular insulator 203 by evacuation through evacuation tube 461, which may then be closed off by means of a valve, a pinch-off, an ultrasonic weld, or the like. Similarly, referring again to FIG. 6A, after baking, de-waxing, and optional green machining, non-sintered cylindrical components 659 may be placed into an enclosure defined by cylindrical enclosure 651 and disk enclosures 655 and the latter closed and sealed, for example by welding. In certain embodiments, residual air is removed from the interior of non-sintered end plug 211 by evacuation through evacuation tube 661, which may then be closed off by means of a valve, a pinch-off, an ultrasonic weld, or the like. In some embodiments, the interior volume of the packed-bed annular insulator 203 and/or the non-sintered end plug 211 is set and maintained at a pressure below atmospheric pressure.

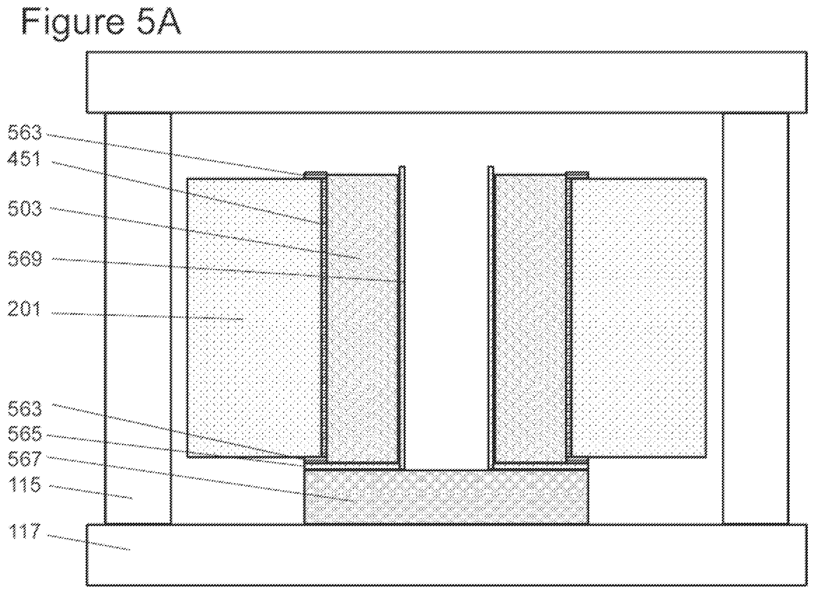

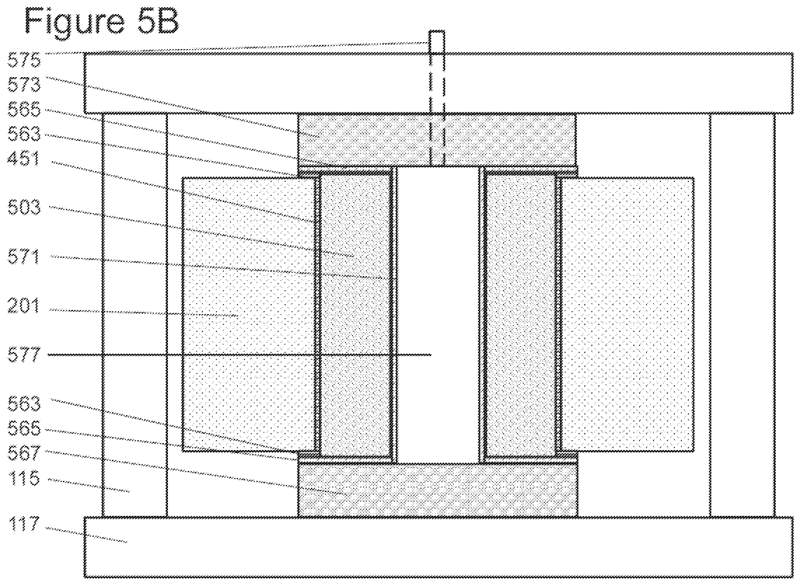

In certain embodiments, one or more non-sintered components 459 may be densified in place by means of a cold isostatic press (CIP) process. For example, as illustrated schematically for one specific embodiment in FIG. 5A, annular flanges 563 are welded to the ends of outer annular enclosure 451, making a close-tolerance fit to the inner diameter of cylindrical enclosure 201. Lower CIP support flange 567 may be placed below cylindrical enclosure 201, making a seal to the lower of annular flanges 563 by means of annular gasket 565. In certain embodiments, CIP support flange 567 is supported axially by lower crown member 117. In certain embodiments, annular gasket 565 includes or consists of rubber, of a type and composition that known in the art of wet-bag cold isostatic pressing. A porous cylindrical mold 569 may then be placed within the cylindrical enclosure 201. In certain embodiments, porous cylindrical mold 569 makes an approximately water-tight seal to annular gasket 565. In certain embodiments, porous cylindrical mold 569 includes or consists of gypsum or a similar material. A slurry, containing a ceramic powder composition, may be added to the annular gap between outer annular enclosure 451 and cylindrical mold 569. A carrier liquid, for example, water, may be allowed to permeate through porous cylindrical mold 569, forming cylindrical cast body 503. In certain embodiments, residual moisture or solvent is removed from cylindrical cast body 503 by means of baking, for example, by applying heat to the inner diameter of porous cylindrical mold 569. Referring to FIG. 5B, porous cylindrical mold 569 is replaced by deformable mold 571 and a second annular gasket 565 placed above upper annular flange 563 and cylindrical cast body 503. In certain embodiments, deformable mold 571 includes or consists of rubber, of a type and composition that known in the art of wet-bag cold isostatic pressing. Deformable mold 571 and annular gaskets 565 may then be joined by a leak-tight seal by means of welding, joining by a silicone or epoxy seal, or the like. Upper CIP support flange 573 may be placed above cylindrical enclosure 201, making a seal to the upper of annular flanges 563 by means of annular gasket 565. In certain embodiments, upper CIP support flange 573 is supported axially by upper crown member 117. Hydraulic inlet 575 may be connected to a high pressure liquid source (not shown). Interior cavity 577 may be filled with pressurized fluid, for example, water, to perform an in situ cold isostatic pressing operation, compressing and densifying cylindrical cast body 503 by pressure transmission across deformable mold 571. After reaching the desired cold isostatic pressing pressure, the fluid may be removed. Upper CIP support flange 573, lower CIP support flange 567, deformable mold 571, and annular gaskets 565 may be removed. In certain embodiments, the compressed cylindrical cast body may be subjected to one or more machining operations and to one or more baking or dewaxing operations. Referring again to FIG. 4, inner annular enclosure 453, upper annular enclosure 455, and lower annular enclosure 457 may be joined to one another and to outer annular enclosure 451 by one or more of welding, brazing, or fastening, encasing in situ formed annular insulator 459.

After baking and/or de-waxing, non-sintered annular components 459 and/or non-sintered cylindrical components 659 may have a density that is between about 30% and about 85%, between about 40% and about 75%, or between about 45% and about 70%, of the theoretical value of 100%-dense ceramic having the same composition. In some embodiments, non-sintered annular components 459 and non-sintered cylindrical components 659 have a thermal conductivity between 0.1 and 10 W/m-K, between 0.2 and 5 W/m-K, between 0.25 and 3 W/m-K, or between 0.3 and 2 W/m-K.

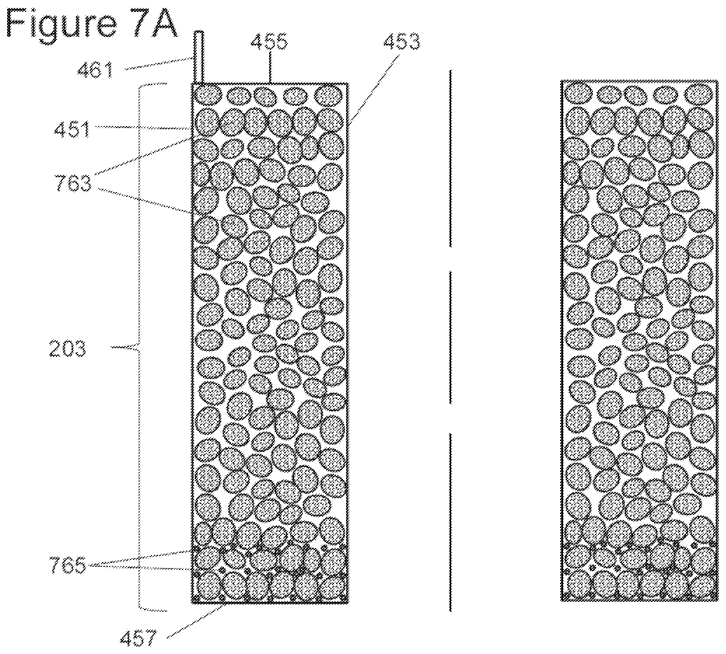

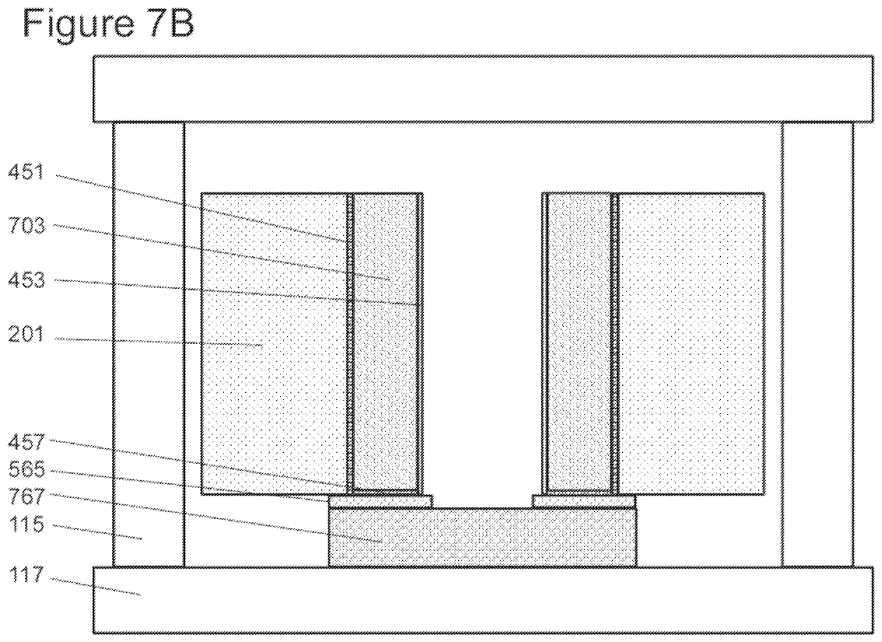

In another set of embodiments, as shown schematically in FIG. 7A, packed-bed annular insulator 203 may include a plurality of sintered primary components 763 in an enclosure consisting of outer annular enclosure 451, inner annular enclosure 453, upper annular enclosure 455, and lower annular enclosure 457. Sintered primary components 763 may have a maximum dimension between about 1 millimeter and about 500 millimeters, between about 2 millimeters and about 100 millimeters, or between about 3 millimeters and about 50 millimeters. Sintered primary components 763 may have a minimum dimension between about 10% and 100% of their maximum dimension. In one specific embodiment, sintered primary components 763 have a rough cylindrical shape, with a length approximately equal to the radial separation between outer annular enclosure 451 and inner annular enclosure 453, and are placed radially, with their length spanning the radial separation. In some embodiments, packed-bed annular insulator 203 further includes a plurality of sintered secondary components 765 within the enclosure. Sintered secondary components 765 may have a maximum dimension between about 5% and about 30% of the maximum dimension of sintered primary components 763. In certain embodiments, sintered secondary components 765 consist of pellets or granules, with a maximum dimension between about 1 millimeter and about 10 millimeters. In some embodiments, packed-bed annular insulator 203 further includes a plurality of sintered tertiary components (not shown). The sintered tertiary components may have a maximum dimension between about 5% and about 30% of the maximum dimension of sintered secondary components 765.

In certain embodiments, one or more of sintered primary components 763, sintered secondary components 765, and the sintered tertiary components may include or consist of a sintered ceramic composition. In certain embodiments, the sintered ceramic composition includes or consists of one or more of zirconia, magnesia-partially-stabilized zirconia, yttria-stabilized zirconia, hafnia, magnesia, yttria, calcia, ceria, silica, alumina, Gd₂Zr₂O₇, (Zr,Hf)₃Y₄O₁₂, tungsten niobate, a rare earth phosphate, a rare earth molybdate, or a mineral formed from one or more of these compositions. The sintered ceramic composition may be fabricated by methods that are well known in the art, such as one or more of ball milling, attrition milling, cold isostatic pressing, die compaction, roll compaction, dewaxing, sintering, jaw crushing, and sieving.

In certain embodiments, one or more of sintered primary components 763, sintered secondary components 765, and the sintered tertiary components may include or consist of a natural rock or mineral composition. In certain embodiments, the natural rock or mineral composition includes or consists of a mafic igneous rock or mineral that is dominated by the silicates pyroxene, amphibole, olivine, and mica, such as basalt. Other naturally-occurring rock compositions, such as granite, are within the range of this invention but may be somewhat less desirable from the standpoint of one or more of a higher thermal conductivity, a lower hardness, or a more complex microstructure than mafic rocks. In a specific embodiment, sintered primary components 763 include or consist of river rocks, sintered secondary components 765 include or consist of river gravel or river pebbles, and the sintered tertiary components include or consist of sand. In some embodiments, the natural rock or mineral is provided in the form of a river rock, which generally has a smooth and/or rounded shape.

In certain embodiments, the surfaces of one or more of sintered primary components 763, sintered secondary components 765, and the sintered tertiary components can be smoothed by tumbling or by similar methods that are known in the art. For example, a tumbling process may include placing sintered components having a similar size and hardness about ⅔ full in a rotary tumbler along with an abrasive grit and enough water to cover the sintered components and then tumbling for a time between about 2 days and about 2 weeks. In certain embodiments, the abrasive grit may include or consist of silicon carbide and may be course (approximately 60/90 grit), medium (approximately 220 grit), or fine (approximately 600 grit).

Inclusion of sintered secondary components 765 and, optionally, sintered tertiary components within packed-bed annular insulator 203 will, in general, increase the thermal conductivity of packed-bed annular insulator 203, but also increase its stability by increasing the number of loading points between one sintered component and another, between the sintered components and the cylindrical heater, and between the sintered components and cylindrical enclosure 201. Cyclic loading and unloading of packed-bed annular insulator 203 during operation of the internally-heated high-pressure apparatus may cause fretting wear at contact points. Increasing the number of contact points is believed to both reduce the extent of fretting wear and reduce any dimensional changes of packed-bed annular insulator 203 resulting from fretting wear, increasing the stability and lifetime of the packed-bed annular insulator 203.

In certain embodiments, packed-bed annular insulator 203, including a plurality of sintered primary components 763, may be formed in place. For example, as illustrated schematically for one specific embodiment in FIG. 7B, lower annular enclosure 457 is joined (for example, by welding) to the lower ends of outer annular enclosure 451 and inner annular enclosure 453. Lower assembly support flange 767 may be placed below cylindrical enclosure 201, making contact with lower annular enclosure 457 by means of optional annular gasket 565. In certain embodiments, assembly support flange 767 is supported axially by lower crown member 117. A predetermined quantity of sintered primary components 763 may then be added to the annular cavity defined by lower annular enclosure 457, outer annular enclosure 451 and inner annular enclosure 453, for example, by pouring the materials into the annular cavity. In certain embodiments, settling is promoted by use of a vibratory compactor, or by related methods that are known in the art. If desired, a removable mandrel (not shown) can be placed within the inner diameter of inner annular enclosure 453 to prevent or minimize deformation during the loading and compaction process. In certain embodiments, cylindrical heater 105 (cf. FIG. 2) is used as a mandrel and left in place during and after the in situ assembly of packed-bed annular insulator 203. In embodiments where a sintered secondary component 765 and, optionally, a sintered tertiary component, is desired, a limited height, for example, between about 50 millimeters and about 500 millimeters of sintered primary components 763 may be added to the annular enclosure, followed by vibratory compaction. The desired quantity of sintered secondary component 765 may then be added, for example, sufficient to just fill the interstices between sintered primary components 763, followed by vibratory compaction. The desired quantity of sintered tertiary component may then be added, for example, sufficient to fill the remaining interstices, followed by vibratory compaction. The process may then be repeated until the entire annular cavity has been filled. Upper annular enclosure 455 may then be joined (for example, by welding) to the upper ends of outer annular enclosure 451 and inner annular enclosure 453. If desired, residual air may be removed from the interior of packed-bed annular insulator 203 containing sintered primary components 763 by evacuation through an evacuation tube, similar to evacuation tube 461 shown in FIG. 4, which may then be closed off by means of a valve, a pinch-off, an ultrasonic weld, or the like.

Referring again to FIG. 2, packed-bed end plugs 211 may be fabricated in a similar way as packed-bed annular insulator 203. For example, as shown schematically in FIG. 6B, packed-bed end plugs 211 containing sintered primary components 763 may be fabricated by placing and compacting sintered primary components 763, and optionally, sintered secondary components 765 and sintered tertiary components (not shown) in an enclosure consisting of cylindrical enclosure 651 and end disk enclosures 655, which may be joined to one another by one or more of welding, brazing, or fastening.

Each of packed-bed annular insulator 203 and packed-bed end cap 211, containing sintered primary components 763, may have a density that is between about 30% and about 98%, between about 40% and about 95%, or between about 50% and about 90%, of the theoretical value of 100%-dense ceramic or mineral having the same composition. In preferred embodiments, packed-bed annular insulator 203 and packed-bed end cap 211 have an overall thermal conductivity between 0.1 and 10 W/m-K, between 0.2 and 5 W/m-K, between 0.25 and 3 W/m-K, or between 0.3 and 2 W/m-K.

In another set of embodiments, one or more of the packed-bed annular insulator 203 and packed-bed end plugs 211 are formed by hot isostatic pressing (HIP) or another similar near-net shape fabrication process. For example, rather than placing multiple, pre-compacted non-sintered annular components 459 in an enclosure as in FIG. 4, ceramic powders and/or pre-compacted ceramic granules can be placed inside a can-shaped structure and densified by hot-isostatic pressing, according to methods that are well known in the art. The shape of the can, for example, approximately annular, can be chosen so that it achieves approximately the desired final shape and dimension after the HIP process. The final dimensions can be achieved by machining the can, still including the densified ceramic, to the desired dimensions. The cans, which include the ceramic powder and/or pre-compacted ceramic granules, can be stacked as needed to form an annular insulator of the desired dimensions. Alternatively, rather than compacting sintered primary components 763 and sintered secondary components 765 in place, as shown in FIG. 7B, the components could be placed into a can and densified by HIP, and final dimensions achieved by machining the can.

The packed-bed annular insulator 203 and packed-bed end plugs 211, together with the enabled monolithic cylindrical enclosure 201, enable considerable cost reduction in the internally-heated high-pressure apparatus while retaining excellent capability for solvothermal crystal growth. The costs can be so low, for example, that it may be cost effective to increase the thickness of the load-bearing annular thermal insulator to the point that the cylindrical enclosure can be cooled only by air cooling, rather than by forced convection of a liquid coolant at its outer diameter.

A method of use according to a specific embodiment can include at least two or more the following activities. Provide an apparatus for high-pressure crystal growth or material processing, such as the ones described above, but there can be others, the apparatus comprising an interior or capsule region (for example, cylindrical in shape) surrounded by a radial restraint structures and supported axially by crown plate members that may be coupled by tie rods or fasteners, the opening regions to the interior region through the crown plate members being closable by crown closure structures. Next, provide a processing chamber or capsule containing a solvent, and then place the processing chamber or capsule within the interior region or capsule region, and close the crown closure structures. Then process the contents disposed within the processing chamber with thermal energy to cause an increase in temperature within the processing chamber or capsule to greater than 200 degrees Celsius to cause the solvent to be superheated. Next, form a crystalline material within the process chamber or capsule due to the process of superheating the solvent. Next, remove thermal energy from the processing chamber or capsule to cause a temperature of the capsule to change from a first temperature to a second temperature, wherein the second temperature is lower than the first temperature. Then open an opening region to the interior region of the high-pressure crystal growth apparatus by removing a crown closure member. Next, remove the processing chamber or capsule from the capsule region. Then open the processing chamber or capsule, and remove the formed crystalline material. The method may include performing one or more additional steps, as desired.

The above sequence of steps provides a method according to an embodiment of the present disclosure. In a specific embodiment, the present disclosure provides a method and resulting crystalline material provided by a high-pressure apparatus having non-sintered, load-bearing, thermally-insulating members. Other alternatives can also be provided where steps are added, one or more steps are removed, or one or more steps are provided in a different sequence without departing from the scope of the claims herein. Details of the present method and structure can be found throughout the present specification and more particularly below.

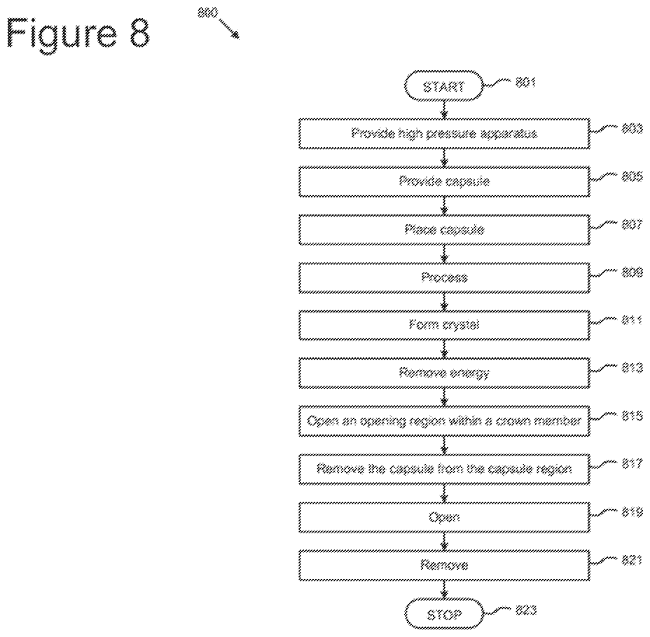

FIG. 8 is a simplified flow diagram 800 of a method of processing a material within a supercritical fluid. This diagram is merely an example of a sequence of method steps, which should not unduly limit the scope of the claims herein.

In a specific embodiment, the method begins with start, step 801. The method begins by providing an apparatus for high pressure crystal or material processing (see step 803), such as the one described above, but there can be others. In certain embodiments, the apparatus has an interior or capsule region (for example, cylindrical in shape) surrounded by radial restraint structures and supported axially by crown plates that may be coupled by tie rods or fasteners. In certain embodiments, the opening regions to the capsule region through crown plate members are closable by crown closure structures.

In a specific embodiment, the method provides a capsule or processing chamber containing a solvent, such as ammonia (see step 805), for example. In a specific embodiment, the method places the capsule (see step 807) containing the solvent and starting seed crystals and polycrystalline nutrient material within an interior region of the capsule region. The method processes the capsule (see step 809) with thermal energy to cause an increase in temperature within the capsule to greater than 200 degrees Celsius to cause the solvent to be superheated.

Referring again to FIG. 8, the method forms a crystalline material (see step 811) from a process of the superheated solvent. In certain embodiments, the crystalline material comprises a gallium-containing nitride crystal such as GaN, AlGaN, InGaN, and others. In a specific embodiment, the method removes thermal energy from the capsule (see step 813) to cause a temperature of the capsule to change from a first temperature to a second temperature, which is lower than the first temperature. Once the energy has been removed and temperature reduced to a suitable level, the method opens an opening region within a crown member (step 815), which mechanically held at least the capsule in place. In certain embodiments, the method removes the capsule from the capsule region (see step 817).

In a specific embodiment, after performing step 817, the capsule is now free from the apparatus. In a specific embodiment, the capsule is opened, step 819. In a certain embodiment, the crystalline material is removed from an interior region of the capsule, step 821. Depending upon the embodiment, there can also be other steps, which can be inserted or added, or certain steps can also be removed. In a specific embodiment, the method ends at step 823.

The above sequence of steps provides a method according to an embodiment of the present disclosure. In a specific embodiment, the present disclosure provides a method and resulting crystalline material provided by a high-pressure apparatus having structured support members. Other alternatives can also be provided where steps are added, one or more steps are removed, or one or more steps are provided in a different sequence without departing from the scope of the claims herein.

In certain embodiments, a gallium-containing nitride crystal or boule grown by methods such as those described above is sliced or sectioned to form wafers. The slicing, sectioning, or sawing may be performed by methods that are known in the art, such as internal diameter sawing, outer diameter sawing, fixed abrasive multiwire sawing, fixed abrasive multiblade sawing, multiblade slurry sawing, multiwire slurry sawing, ion implantation and layer separation, or the like. The wafers may be lapped, polished, and chemical-mechanically polished according to methods that are known in the art.

One or more active layers may be deposited on the well-crystallized gallium-containing nitride wafer. The active layer may be incorporated into an optoelectronic or electronic devices such as at least one of a light emitting diode, a laser diode, a photodetector, a photodiode, an avalanche photodiode, a transistor, a rectifier, and a thyristor; one of a transistor, a rectifier, a Schottky rectifier, a thyristor, a p-i-n diode, a metal-semiconductor-metal diode, high-electron mobility transistor, a metal semiconductor field effect transistor, a metal oxide field effect transistor, a power metal oxide semiconductor field effect transistor, a power metal insulator semiconductor field effect transistor, a bipolar junction transistor, a metal insulator field effect transistor, a heterojunction bipolar transistor, a power insulated gate bipolar transistor, a power vertical junction field effect transistor, a cascode switch, an inner sub-band emitter, a quantum well infrared photodetector, a quantum dot infrared photodetector, a solar cell, and a diode for photoelectrochemical water splitting and hydrogen generation.

While the foregoing is directed to embodiments of the present disclosure, other and further embodiments of the disclosure may be devised without departing from the basic scope thereof, and the scope thereof is determined by the claims that follow.

What is claimed is:

1. An apparatus for solvothermal crystal growth, the apparatus comprising:
a cylindrical-shaped enclosure;
a cylindrical heater comprising a first end, a second end and a cylindrical wall that extends between the first end and the second end, wherein an interior surface of the cylindrical wall defines a capsule region;
a first end closure member disposed proximate to the first end of the cylindrical heater, the first end closure member being configured to provide axial support for a capsule disposed within the capsule region;
a load-bearing annular insulating member disposed between an inner surface of the cylindrical-shaped enclosure and an outer surface of the cylindrical wall of the cylindrical heater; and
a first end plug disposed between the first end of the cylindrical heater and the first end closure,
wherein the load-bearing annular insulating member or the first end plug comprises a packed-bed ceramic composition, the packed-bed ceramic composition being characterized by a density that is between about 30% and about 98% of a theoretical density of a 100%-dense ceramic having the same composition.

2. The apparatus of claim 1, wherein the packed-bed ceramic composition comprises a non-sintered ceramic composition that has a thermal conductivity between about 0.1 and about 10 watts per meter-Kelvin.

3. The apparatus of claim 2, wherein the non-sintered ceramic composition comprises a powder that has a particle size between about 100 nanometers and about 150 micrometers.

4. The apparatus of claim 2, wherein the non-sintered ceramic composition comprises a green body formed from one or more powder compositions.

5. The apparatus of claim 4, wherein the one or more powder compositions comprise one or more of zirconia, magnesia-partially-stabilized zirconia, yttria-stabilized zirconia, hafnia, magnesia, yttria, calcia, ceria, silica, alumina, Gd₂Zr₂O₇, (Zr,Hf)₃Y₄O₁₂, tungsten niobate, a rare earth phosphate, a rare earth molybdate, or a mineral formed from one or more of these compositions.

6. The apparatus of claim 4, wherein the one or more powder compositions further comprise a sintering-inhibiting composition.

7. The apparatus of claim 6, wherein sintering-inhibiting composition comprises one or more of graphite, boron nitride, molybdenum disulfide, or tungsten disulfide.

8. The apparatus of claim 1, wherein the load-bearing annular insulating member comprises a non-sintered annular ceramic composition disposed within a metallic enclosure.

9. The apparatus of claim 8, wherein the non-sintered annular ceramic composition comprises two or more radial segments.

10. The apparatus of claim 8, wherein an interior region of the enclosure comprises a pressure below atmospheric pressure.

11. The apparatus of claim 1, wherein the packed-bed ceramic composition is characterized by a density that is between about 45% and about 70% of a theoretical density of a 100%-dense ceramic having the same composition and by a thermal conductivity between about 0.25 and about 3 watts per meter-Kelvin.

12. The apparatus of claim 1, wherein the load-bearing annular insulating member or the end plug comprises a plurality of sintered primary components disposed within an enclosure, wherein each of the plurality of sintered primary components have a maximum dimension between about 1 millimeter and about 500 millimeters.

13. The apparatus of claim 12, wherein each of the plurality of sintered primary components have a maximum dimension between about 2 millimeters and about 100 millimeters.

14. The apparatus of claim 12, further comprising a plurality of sintered secondary components disposed within the enclosure, wherein each of the plurality of sintered secondary components have a maximum dimension between about 5% and about 30% of the maximum dimension of the sintered primary components.

15. The apparatus of claim 14, further comprising a plurality of sintered tertiary components, wherein each of the sintered tertiary components have a maximum dimension between about 5% and about 30% of the maximum dimension of the sintered secondary components.

16. The apparatus of claim 12, wherein each of the plurality of sintered primary components comprises one or more of zirconia, magnesia-partially-stabilized zirconia, yttria-stabilized zirconia, hafnia, magnesia, yttria, calcia, ceria, silica, alumina, Gd₂Zr₂O₇, (Zr,Hf)₃Y₄O₁₂, tungsten niobate, a rare earth phosphate, or a rare earth molybdate, or a mineral formed from one or more of these compositions.

17. The apparatus of claim 12, wherein each of the plurality of sintered primary components comprises a natural rock or mineral composition.

18. The apparatus of claim 17, wherein the natural rock or mineral composition comprises at least one of basalt, a mafic rock composition, or granite.

19. The apparatus of claim 12, wherein each of the plurality of sintered primary components comprises river rocks.

20. The apparatus of claim 14, wherein each of the plurality of sintered primary components comprise river rocks, and each of the plurality of sintered secondary components comprise river gravel or river pebbles.
